(19) United States
(12) Patent Application Publication
(10) Pub. No.: US 2026/0013190 A1
(43) Pub. Date: Jan. 8, 2026

(54) SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/901,404

(22) Filed: Sep. 30, 2024

(30) Foreign Application Priority Data
Jul. 5, 2024 (CN) 202410899301.6

(51) Int. Cl. H01L 29/36; H01L 29/16; H01L 29/20

(52) U.S. Cl. CPC H10D 62/605; H10D 62/83; H10D 62/8503

(57) ABSTRACT

A semiconductor structure includes an N-type silicon substrate, where the N-type silicon substrate includes alternating delta-doped layers and uniformly doped layers; and an epitaxial structure located on the N-type silicon substrate, where a material of the epitaxial structure includes a nitride material. In the present disclosure, the N-type silicon substrate may effectively suppress a diffusion of Ga/Al and the like from the epitaxial structure toward the substrate, thereby reducing a possibility of generating parasitic capacitance and leakage current, and greatly improving reliability of a device. In the present disclosure, an N-type delta-doped layers and an N-type uniformly doped layers are alternately disposed, which may further achieve depletion of multi-layer space charge, and further avoid the parasitic capacitance and the leakage current.

### CROSS-REFERENCE TO RELATED APPLICATIONS

The present disclosure claims priority to Chinese Patent Application No. 202410899301.6, filed on Jul. 5, 2024, the content of which is hereby incorporated by reference in its entirety.

### TECHNICAL FIELD

The present disclosure relates to the field of semiconductor technologies, and in particular, to a semiconductor structure.

### BACKGROUND

As a typical representation of third-generation semiconductor materials, a wide bandgap semiconductor material III-V compound has excellent characteristics of a large bandgap, high pressure resistance, high temperature resistance, high electron saturation velocity and drift velocity, easy formation of a high-quality heterostructure, and is very suitable for manufacturing high-temperature, high-frequency and high-power electronic devices.

Group III-V compound materials may be formed on a silicon substrate by an epitaxial growth process. In an actual product, Ga/Al and the like in the Group III-V compound materials epitaxially grown on the silicon substrate diffuse into the silicon substrate easily, and a P-type semiconductor conductive region is formed in the silicon substrate, resulting in parasitic capacitance and leakage current, thereby greatly reducing reliability of the device.

### SUMMARY

In view of this, embodiments of the present disclosure provide a semiconductor structure to solve problems of parasitic capacitance and leakage current caused by a group III-V material device on a silicon substrate, so as to improve reliability of a device.

According to one aspect of the present disclosure, an embodiment of the present disclosure provides a semiconductor structure, including: an N-type silicon substrate, where the N-type silicon substrate includes alternating delta-doped layers and uniformly doped layers; and an epitaxial structure located on the N-type silicon substrate, where a material of the epitaxial structure includes a nitride material.

As an optional embodiment, a thickness of each of the delta-doped layers is less than 50 nm.

As an optional embodiment, a thickness of the uniformly doped layers is greater than twice a thickness of the delta-doped layers.

As an optional embodiment, the thickness of the uniformly doped layers is greater than five times the thickness of the delta-doped layers.

As an optional embodiment, a concentration of an N-type doping ion in the uniformly doped layers is less than 1×10¹⁶ cm⁻³.

As an optional embodiment, a concentration of the N-type doping ion in the delta-doped layers is greater than ten times a concentration of the N-type doping ion in the uniformly doped layers.

As an optional embodiment, thicknesses of a plurality of the delta-doped layers gradually increase along a direction close to the epitaxial structure.

As an optional embodiment, spacing distances of a plurality of the delta-doped layers gradually decrease along a direction close to the epitaxial structure.

As an optional embodiment, doping concentrations of a plurality of the delta-doped layers gradually increase along a direction close to the epitaxial structure.

As an optional embodiment, N-type doped ions of the N-type silicon substrate includes at least one of phosphorus, nitrogen or arsenic.

As an optional embodiment, a thickness of the N-type silicon substrate is less than 2 um.

As an optional embodiment, the N-type silicon substrate includes a P-type semiconductor region, the epitaxial structure at least includes one element, the element of the epitaxial structure diffuses into the N-type silicon substrate, and the P-type semiconductor region is formed in the N-type silicon substrate.

As an optional embodiment, the element includes a B element, a Ga element, an Al element, an Mg element, an In element, or a Zn element.

As an optional embodiment, a width of the P-type semiconductor region decreases in a direction from the epitaxial structure toward the N-type silicon substrate.

As an optional embodiment, a reduction speed of the width of the P-type semiconductor region in the delta-doped layers is greater than a reduction speed of the width of the P-type semiconductor region in the uniformly doped layers in the direction from the epitaxial structure toward the N-type silicon substrate.

As an optional embodiment, a doping concentration of the element of the P-type semiconductor region decreases in a direction from the epitaxial structure toward the N-type silicon substrate.

As an optional embodiment, a reduction speed of the doping concentration of the element of the P-type semiconductor region in the delta-doped layers is greater than a reduction speed of the doping concentration of the element of the P-type semiconductor region in the uniformly doped layers in the direction from the epitaxial structure toward the N-type silicon substrate.

As an optional embodiment, a concentration of a P-type doping ion in the P-type semiconductor region is less than 1×10¹⁸ cm⁻³.

As an optional embodiment, the semiconductor structure further includes: an AIN layer located on one side, away from the epitaxial structure, of the N-type silicon substrate, and a silicon supporting substrate located on one side, away from the epitaxial structure, of the AIN layer.

As an optional embodiment, the semiconductor structure further includes: an electrode located on the epitaxial structure, where when the semiconductor structure is a triode structure, the electrode includes a source electrode and a drain electrode, and a gate electrode located between the source electrode and the drain electrode; and when the semiconductor structure is a diode structure, the electrode includes a positive electrode and a negative electrode.

### BRIEF DESCRIPTION OF THE DRAWINGS

FIG. 1 is a schematic structural diagram of a semiconductor structure according to an embodiment of the present disclosure.

FIG. 2 and FIG. 3 are schematic structural diagrams of a semiconductor structure according to some embodiments of the present disclosure.

FIG. 4 is a schematic structural diagram of a semiconductor structure according to an embodiment of the present disclosure.

FIG. 5 is a schematic structural diagram of a semiconductor structure according to an embodiment of the present disclosure.

FIG. 6 is a schematic structural diagram of a semiconductor structure according to an embodiment of the present disclosure.

FIG. 7 and FIG. 8 are schematic structural diagrams of a semiconductor structure according to some embodiments of the present disclosure.

### DETAILED DESCRIPTION OF THE EMBODIMENTS

The technical solutions in the embodiments of the present disclosure will be clearly described below with reference to the accompanying drawings in the embodiments of the present disclosure. Apparently, the described embodiments are a part of the embodiments of the present disclosure, rather than all the embodiments. All other embodiments obtained by a person of ordinary skill in the art based on the embodiments of the present disclosure without creative efforts shall fall within the protection scope of the present disclosure.

In order to solve problems of parasitic capacitance and leakage current caused by a group III-V material device on a silicon substrate, so as to improve reliability of a device. The present disclosure provides a semiconductor structure, the semiconductor structure includes an N-type silicon substrate, where the N-type silicon substrate includes alternating delta-doped layers and uniformly doped layers; and an epitaxial structure located on the N-type silicon substrate, where a material of the epitaxial structure includes a nitride material. In the present disclosure, the N-type silicon substrate may effectively suppress a diffusion of Ga/Al and the like from the epitaxial structure toward the substrate, thereby reducing a possibility of generating parasitic capacitance and leakage current, and greatly improving the reliability of a device. In the present disclosure, an N-type delta-doped layers and an N-type uniformly doped layers are alternately disposed, which may further achieve depletion of multi-layer space charge, and further avoid the parasitic capacitance and the leakage current.

The semiconductor structure mentioned in the present disclosure is further illustrated below with reference to FIG. 1 to FIG. 8.

FIG. 1 is a schematic structural diagram of a semiconductor structure according to an embodiment of the present disclosure. As shown in FIG. 1, the semiconductor structure includes: an N-type silicon substrate 10, where the N-type silicon substrate 10 includes alternating delta-doped layers 101 and uniformly doped layers 102; and an epitaxial structure 20 located on the N-type silicon substrate 10, where a material of the epitaxial structure 20 includes a nitride material.

In this embodiment, N-type doped ions of the N-type silicon substrate 10 include at least one of phosphorus, nitrogen or arsenic. A concentration of the N-type doping ion in the N-type silicon substrate 10 is less than 1×10¹⁶ cm⁻³,that is, the concentration of the N-type doping ion in the uniformly doped layers 102 is less than 1×10¹⁶ cm⁻³, the delta-doped layers 101 may be formed in the N-type silicon substrate 10 by ion implantation, and the implanted ion may also be at least one of the phosphorus, the nitrogen or the arsenic, The concentration of the N-type doping ion in the formed delta-doped layers 101 is greater than ten times the concentration of the N-type doping ion in the uniformly doped layers 102, for example, the concentration of the N-type doping ion in the delta-doped layers 101 is 1× 10¹⁷ cm⁻³.

In this embodiment, a thickness of the N-type silicon substrate 10 is less than 2 μm, a thickness of each of the delta-doped layers 101 is less than 50 nm, and a thickness of the uniformly doped layers 102 is greater than twice a thickness of the delta-doped layers 101. Optionally, the thickness of the uniformly doped layers 102 is greater than five times the thickness of the delta-doped layers 101, or the thickness of the uniformly doped layers 102 is greater than ten times the thickness of the delta-doped layers 101.

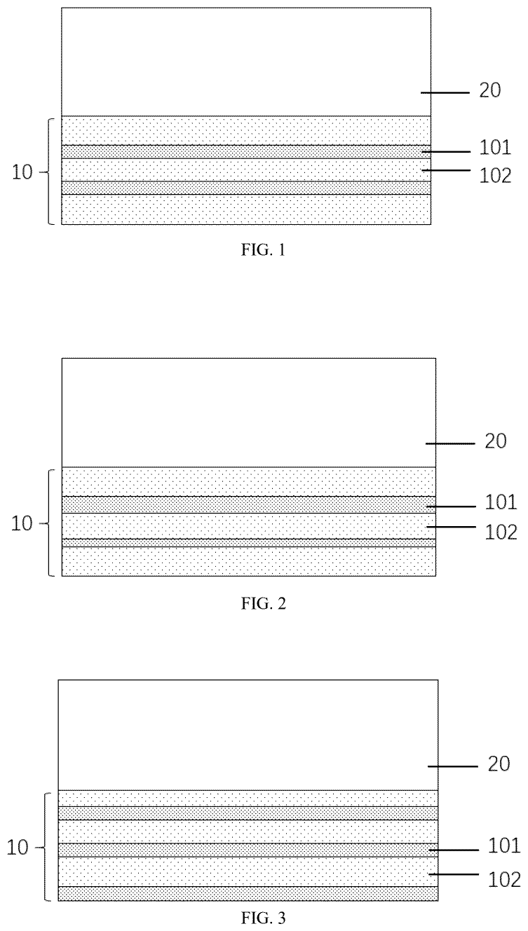

In an embodiment, FIG. 2 to FIG. 3 are schematic structural diagrams of a semiconductor structure according to some embodiments of the present disclosure. As shown in FIG. 1, the thickness, spacing distance or doping concentration of the plurality of delta-doped layers 101 are uniform. Optionally, as shown in FIG. 2, thicknesses of a plurality of the delta-doped layers 101 gradually increase along a direction close to the epitaxial structure 20. Optionally, as shown in FIG. 3, spacing distances of a plurality of the delta-doped layers 101 gradually decrease along the direction close to the epitaxial structure 20. Optionally, doping concentrations of a plurality of the delta-doped layers 101 gradually increase along the direction close to the epitaxial structure 20. Since the delta-doped layers 101 may effectively suppress the diffusion of elements in the epitaxial structure 20 toward the N-type silicon substrate 10, by designing a greater thickness, doping concentration or density of the delta-doped layers 101 that close to the epitaxial structure 20, the ability to suppress the diffusion of the elements from the epitaxial structure 20 toward the N-type silicon substrate 10 may be further improved.

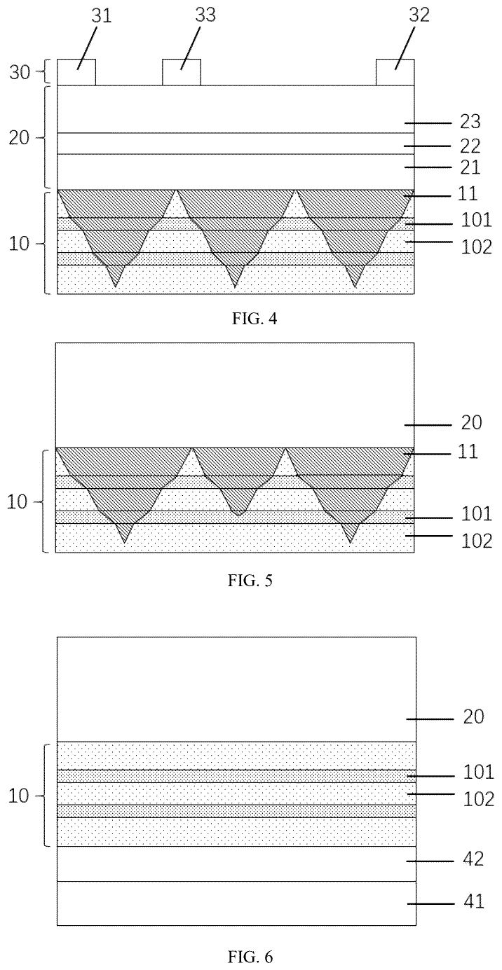

In an embodiment, FIG. 4 is a schematic structural diagram of a semiconductor structure according to an embodiment of the present disclosure. As shown in FIG. 4, the N-type silicon substrate 10 includes a P-type semiconductor region 11, the epitaxial structure 20 at least includes one element, the element of the epitaxial structure 20 diffuses into the N-type silicon substrate 10, and the P-type semiconductor region 11 is formed in the N-type silicon substrate 10. A concentration of a P-type doping ion in the P-type semiconductor region 11 is less than 1×10¹⁸ cm⁻³. The element in the epitaxial structure 20 includes a B element, a Ga element, an Al element, an Mg element, an In element, or a Zn element. As shown in FIG. 4, a width of the P-type semiconductor region 11 decreases in a direction from the epitaxial structure 20 toward the N-type silicon substrate 10, and a reduction speed of the width of the P-type semiconductor region 11 in the delta-doped layers 101 is greater than a reduction speed of the width of the P-type semiconductor region 11 in the uniformly doped layers 102 in the direction from the epitaxial structure 20 toward the N-type silicon substrate 10. In this embodiment, a doping concentration of the element of the P-type semiconductor region 11 also decreases in the direction from the epitaxial structure 20 toward the N-type silicon substrate 10, and a reduction speed of the doping concentration of the element of the P-type semiconductor region 11 in the delta-doped layers 101 is greater than a reduction speed of the doping concentration of the element of the P-type semiconductor region 11 in the uniformly doped layers 102 in the direction from the epitaxial structure 20 toward the N-type silicon substrate 10. The N-type delta-doped layers 101 and the N-type uniformly doped layers 102 are alternately disposed, which may suppress the diffusion of Ga/Al and the like in the epitaxial structure 20, thereby reducing the possibility of generating parasitic capacitance and leakage current. On the other hand, a space charge region is formed by the N-type silicon substrate 10 and the P-type semiconductor region 11 formed by diffusion in the N-type silicon substrate 10, conductive electrons and holes in the space charge region are completely depleted, the space charge region is basically insulated and is similar to a high resistance region, and a breakdown electric field of a device may be improved, thereby further reducing the possibility of generating the parasitic capacitance and the leakage current.

In an embodiment, FIG. 5 is a schematic structural diagram of a semiconductor structure according to an embodiment of the present disclosure. Since the epitaxial structure 20 is not perfectly uniform in an epitaxial process, there will be local defects, and the distribution of elements in the epitaxial structure 20 is also not completely uniform, resulting in that widths or thicknesses of a plurality of the P-type semiconductor regions 11 formed by elements diffusion are not exactly same. As shown in FIG. 5, a width of at least one P-type semiconductor region 11 is different from a width of the other P-type semiconductor region 11, and/or a thickness of at least one P-type semiconductor region 11 is different from a thickness of the other P-type semiconductor region 11.

In an embodiment, FIG. 6 is a schematic structural diagram of a semiconductor structure according to an embodiment of the present disclosure. As shown in FIG. 6, the semiconductor structure further includes: an AIN layer 42 located on one side, away from the epitaxial structure 20, of the N-type silicon substrate 10, and a silicon supporting substrate 41 located on one side, away from the epitaxial structure 20, of the AlN layer 42. In this embodiment, the semiconductor structure is a Si/AlN/Si/nitride stack, the AlN layer 42 may function as a stress balance, so that the nitride epitaxial structure 20 has better crystal quality.

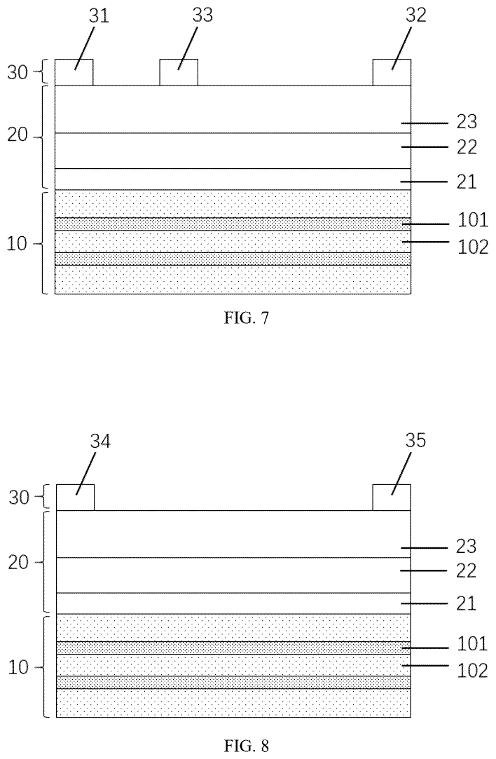

In an embodiment, FIG. 7 to FIG. 8 are schematic structural diagrams of a semiconductor structure according to some embodiments of the present disclosure. As shown in FIG. 7, the epitaxial structure 20 includes a nitride nucleation layer 21, a nitride buffer layer 22, and a nitride channel layer 23 that are stacked. The semiconductor structure further includes: an electrode 30 located on the epitaxial structure 20, where when the semiconductor structure is a triode structure, the electrode 30 includes a source electrode 31 and a drain electrode 32, and a gate electrode 33 located between the source electrode 31 and the drain electrode 32. The nitride triode structure is configured to manufacture a high voltage resistant radio frequency device. As shown in FIG. 8, when the semiconductor structure is a diode structure, the electrode 30 includes a positive electrode 34 and a negative electrode 35. In the silicon substrate of the nitride diode structure, the space charge regions of the P-type semiconductor region 11 and the N-type silicon substrate 10 are formed, which may enhance a reverse breakdown voltage of the diode, where the positive electrode 34 is a Schottky contact, and the negative electrode 35 is an ohmic contact.

The present disclosure provides a semiconductor structure, the semiconductor structure includes an N-type silicon substrate, where the N-type silicon substrate includes alternating delta-doped layers and uniformly doped layers; and an epitaxial structure located on the N-type silicon substrate, where a material of the epitaxial structure includes a nitride material. In the present disclosure, the N-type silicon substrate may effectively suppress a diffusion of Ga/Al and the like from the epitaxial structure toward the substrate, thereby reducing a possibility of generating parasitic capacitance and leakage current, and greatly improving reliability of a device. In the present disclosure, an N-type delta-doped layers and an N-type uniformly doped layers are alternately disposed, which may further achieve depletion of multi-layer space charge, and further avoid parasitic capacitance and leakage current.

It should be understood that the terms “include” and variations thereof used in the present disclosure are open ended, that is, “including but not limited to”. The term “an embodiment” means “at least one embodiment”; the term “another embodiment” means “at least one further embodiment”. In this specification, the schematic representation of the above terms does not necessarily refer to the same embodiment or example. Furthermore, the particular features, structures, materials, or characteristics described may be combined in any suitable manner in any one or more embodiments or examples. In addition, different embodiments or examples described in this specification and features of different embodiments or examples may be combined and combined by a person skilled in the art without contradicting each other.

The above are only preferred embodiments of the present disclosure and are not intended to limit the present disclosure, and any modification, equivalent replacement, etc. made within the spirit and principle of the present disclosure should be included in the protection scope of the present disclosure.

What is claimed is:

1. A semiconductor structure, comprising:
an N-type silicon substrate, wherein the N-type silicon substrate comprises alternating delta-doped layers and uniformly doped layers; and
an epitaxial structure located on the N-type silicon substrate, wherein a material of the epitaxial structure comprises a nitride material.

2. The semiconductor structure according to claim 1, wherein a thickness of each of the delta-doped layers is less than 50 nm.

3. The semiconductor structure according to claim 2, wherein a thickness of the uniformly doped layers is greater than twice a thickness of the delta-doped layers.

4. The semiconductor structure according to claim 3, wherein the thickness of the uniformly doped layers is greater than five times the thickness of the delta-doped layers.

5. The semiconductor structure according to claim 1, wherein a concentration of an N-type doping ion in the uniformly doped layers is less than 1×10¹⁶ cm⁻³.

6. The semiconductor structure according to claim 5, wherein the concentration of the N-type doping ion in the delta-doped layers is greater than ten times a concentration of the N-type doping ion in the uniformly doped layers.

7. The semiconductor structure according to claim 1, wherein thicknesses of a plurality of the delta-doped layers gradually increase along a direction close to the epitaxial structure.

8. The semiconductor structure according to claim 1, wherein spacing distances of a plurality of the delta-doped layers gradually decrease along a direction close to the epitaxial structure.

9. The semiconductor structure according to claim 1, wherein doping concentrations of a plurality of the delta-doped layers gradually increase along a direction close to the epitaxial structure.

10. The semiconductor structure according to claim 1, wherein N-type doped ions of the N-type silicon substrate comprise at least one of phosphorus, nitrogen or arsenic.

11. The semiconductor structure according to claim 1, wherein a thickness of the N-type silicon substrate is less than 2 μm.

12. The semiconductor structure according to claim 1, wherein the N-type silicon substrate comprises a P-type semiconductor region, the epitaxial structure at least comprises one element, the element of the epitaxial structure diffuses into the N-type silicon substrate, and the P-type semiconductor region is formed in the N-type silicon substrate.

13. The semiconductor structure according to claim 12, wherein the element comprises a B element, a Ga element, an Al element, an Mg element, an In element, or a Zn element.

14. The semiconductor structure according to claim 12, wherein a width of the P-type semiconductor region decreases in a direction from the epitaxial structure toward the N-type silicon substrate.

15. The semiconductor structure according to claim 14, wherein a reduction speed of the width of the P-type semiconductor region in the delta-doped layers is greater than a reduction speed of the width of the P-type semiconductor region in the uniformly doped layers in the direction from the epitaxial structure toward the N-type silicon substrate.

16. The semiconductor structure according to claim 12, wherein a doping concentration of the element of the P-type semiconductor region decreases in a direction from the epitaxial structure toward the N-type silicon substrate.

17. The semiconductor structure according to claim 16, wherein a reduction speed of the doping concentration of the element of the P-type semiconductor region in the delta-doped layers is greater than a reduction speed of the doping concentration of the element of the P-type semiconductor region in the uniformly doped layers in the direction from the epitaxial structure toward the N-type silicon substrate.

18. The semiconductor structure according to claim 12, wherein a concentration of a P-type doping ion in the P-type semiconductor region is less than 1×10¹⁸ cm⁻³.

19. The semiconductor structure according to claim 1, further comprising:
an AlN layer located on one side, away from the epitaxial structure, of the N-type silicon substrate, and a silicon supporting substrate located on one side, away from the epitaxial structure, of the AlN layer.

20. The semiconductor structure according to claim 1, further comprising:
an electrode located on the epitaxial structure, wherein when the semiconductor structure is a triode structure, the electrode comprises a source electrode and a drain electrode, and a gate electrode located between the source electrode and the drain electrode; and when the semiconductor structure is a diode structure, the electrode comprises a positive electrode and a negative electrode.
